(19) United States
(12) Patent Application Publication
(10) Pub. No.: US 2011/0136345 A1
(43) Pub. Date: Jun. 9, 2011

(54) Process for the Manufacture of Etched Items

(75) Inventor: Marcello Riva, Hannover (DE)

(73) Assignee: SOLVAY FLUOR GMBH, Hannover (DE)

(21) Appl. No.: 13/003,808

(22) PCT Filed: Jul. 14, 2009
(86) PCT No.: PCT/EP2009/058996

§ 371 Date: Jan. 12, 2011

Related U.S. Application Data
(60) Provisional application No. 61/080,815, filed on Jul. 15, 2008.

(51) Int. Cl. H01L 21/306; C09K 13/00

(52) U.S. Cl. 438/694; 252/79.1; 257/E21.219

(57) ABSTRACT

C4 compounds selected from the group of trifluorobutadienes and tetrafluorobutenes can be used as etching gases, especially for anisotropic etching in the production of etched items, for example, of semiconductors, e.g. semiconductor memories or semiconductor logic circuits, flat panels, or solar cells. Preferred compounds are 1,1,3-trifluoro-1,3-butadiene, (E)-1,1,1,3-tetrafluoro-2-butene, 2,4,4,4-tetrafluoro-1-butene and (Z)-1,1,1,3-tetrafluoro-2-butene which can be obtained from halotetrafluorobutanes or 1,1,1,3,3-pentafluorobutane by thermal, base-induced or catalytic dehydrohalogenation, especially by catalytic dehydrofluorination. The C4 compounds have the especial advantage that they allow the direct etching of photoresist-protected items where the pattern of the photoresist is defined by light of a wavelength of 193 nm, or even “extreme UV light”. Nodes with a very narrow gap, for example, nodes with gaps of 130 nm, 90 nm, 45 or 32 nm and even 22 nm can be produced.

The invention concerns a process for the preparation of etched items, e.g. semiconductors, solar cells, and flat panels.

During the manufacture of electronic devices, for example, semiconductor logics, optical and memory devices, for example, Dynamic Random Access Memories (DRAMs) or Central Processing Units (CPUs), logics or capacitors, often one or more steps of etching must be performed. Often, the material to be etched is silicon. Other materials to be etched are silicon oxide, silicon nitride, or low-k dielectrics, for example, FSG (fluorosilicate glass), or C-doped silicon dioxide. A preferred method of etching the items is performed using plasma in the presence of an etchant.

U.S. Pat. No. 4,784,720 discloses a plasma dry etching process for trench etching wherein a selective sidewall passivation is accomplished to control the profile of the trench being etched. The passivating deposit can be reduced or etched at predetermined times using etching agents, for example, SF₆ or NF₃.

WO 97/24750 discloses etching of silicon dioxide using unsaturated fluorocarbon gases of formula CₙF₂ₙ, especially C₂F₄ and C₃F₆.

It is observed that formed fluoropolymers are less stable over oxygen containing layers, e.g. silicon oxide layers, and thus enhance the selectivity of the etching method over barrier layers of other materials, e.g. Si₃N₄. It is stated that sharp side walls are formed when these gases are applied. It is assumed that the unsaturated gases form polymers on the surface of materials not to be etched (i.e. on the photoresist and the material beneath SiO₂).

U.S. Pat. No. 6,508,948 discloses a method for etching features into a substrate by removing substrate material from selected areas. A patterned mask is provided and the item is placed in a plasma chamber. Halogenated heterocyclic hydrocarbons, for example, perfluoropyridine, are introduced into the chamber, and etching is started. Additional etching agents, e.g. CHF₃, C₃F₆ or C₄F₆ or carrier gases, e.g. nitrogen or argon, can be added. The process can be applied to perform microfabrication of semi-conductor-based logic, memory and optoelectronic devices and micromechanical systems using anisotropic etching.

U.S. Pat. No. 6,174,451 discloses oxide etching using hexafluorobutadiene, pentafluoropropylene and trifluoropropyne which are commercially available.

Problem of the present invention is to provide useful etching agents, especially for use in anisotropic etching.

Consequently, the present invention provides for a process for producing an etched item including at least one step of anisotropically etching the item wherein the etching of the item is performed in the presence of a fluorinated unsaturated C4 compound selected from the group consisting of trifluorobutadienes and tetrafluorobutenes. Preferably, 1,1,3-trifluorobutadiene and 1,1,1,3-tetrafluorobutenes are applied. The fluorinated unsaturated C4 compounds act as etching agent, and especially as anisotropically etching agent. The term “an item” includes the singular and the plural, especially one item or a plurality of items, e.g. 2, 3, 4, 5 or more items. If only one item or a plurality of items are etched depends on the capacity of the used plasma chamber. If multiple items shall be etched simultaneously, a respective plasma chamber must be applied.

In the present invention, the terms “comprising” and “containing” include the meaning of “consisting of”. Often in the description, it is expressly mentioned when the meaning “consisting of” is preferred.

The fluorinated butenes and butadienes can be prepared by thermal or catalytic dehydrofluorination of the respective hydrofluorocarbons or by hydrodebromination of respective bromofluorobutenes. 1,1,2-trifluoro-1,3-butadiene can be prepared, for example, by hydrodebromination of CF₂═CF—H₂CH₂Br with an aqueous alkali metal hydroxide solution in the presence of a phase transfer catalyst as described in U.S. Pat. No. 4,902,835. 1,1,3-rifluorobutadiene, 2,4,4,4-tetrafluoro-1-butene and (E) and (Z)-,1,1,3-etrafluoro-2-butenes can be prepared as described in WO 2004/096737 by dehydrofluorination of 1,1,1,3,3-pentafluorobutane thermally, for example, at a temperature in the range of 400 to 550° C., by means of a base, for example, an alkali metal hydroxide or a tertiary amine, or in the presence of a catalyst, for example, chromium on activated carbon. They can also be prepared as described in WO 2009/010472 by dehydrofluorination of 1,1,1,3,3-pentafluorobutane over a high-surface aluminium fluoride catalyst.

The above-mentioned dehydrofluorination reaction products can be separated by conventional means, for example, by distillation. The trifluorobutadiene and tetrafluorobutene compounds can be applied as single etchant compounds or in the form of mixtures, especially in the form of azeotropes. It is preferred that single compounds are applied (but optionally in mixture with, as will be described later, additive gases or diluent gases, e.g. nitrogen, helium, xenon, or argon) because reaction conditions are more easily defined for single etching compounds.

The term “single” denotes that the etchant gas contains a single unsaturated C4 unsaturated fluorocarbon compound selected from the group consisting of trifluorobutadienes and tetrafluorobutenes, but no further carbon containing etchant or other fluorosubstituted etchants. The term “single” does not exclude the presence of additive gases or diluent gases, such as nitrogen, helium, xenon, or argon.

The (E) and (Z) isomers of 1,1,1,3-tetrafluoro-2-butene can be applied as a mixture, but they are also preferably applied as single compounds after isolation which is possible by distillation.

The fluorinated unsaturated C4 compounds can be applied for those purposes in etching processes for which fluorinated carbons are generally used. They can be used in etching processes, preferably for the manufacture of semiconductor memories and logics, like e.g., DRAMs and CPUs.

They are preferably applied to etch dielectric materials, for example, silicon dioxide, silicon nitride, low and ultra low-k dielectrics like FSG, carbon doped dielectrics and similar material.

The fluorinated unsaturated C4 compounds are especially suitable in processes including one or more steps of anisotropic etching (optionally diluted with nitrogen, helium, argon, xenon or other additive or diluent gases). Helium and especially nitrogen are predominantly diluent gases. Argon and xenon are additive gases which dilute the fluorinated unsaturated C4 compound or compounds, but which also can influence the selectivity of the etching process

The conditions during etching correspond to those usually applied. For example, direct plasma or indirect plasma can be applied. Often, the pressure in the plasma chamber is equal to or below 150 Pa. Preferably, the pressure is from 1 to 120 Pa.

The fluorinated unsaturated C4 compounds of the present invention are especially suitable in the field of technique as described in U.S. Pat. No. 6,174,451 and especially WO 2000/30168 directed to the production of silicon integrated circuits.

The technique described in WO 2000/30168 is explained here in detail. It concerns generally the etching of silicon integrated circuits, and especially the etching of dielectrics, for example, silicon oxide and related materials in a process that is capable of greatly reduced etching rates for silicon nitride and other non-oxide materials but still producing a vertical profile in the oxide. Oxide etching, a somewhat generic term used for silica, SiO₂, and slightly non-stoichiometric compositions SiOₓ, and for closely related materials, for example, oxide glasses, e.g. borophosphosilicate glass, and even silicon oxynitride, presents some difficult challenges. Oxide materials, optionally doped by e.g. fluorine (fluorosilicate glass, “FSG”) or carbon (e.g. Black Diamond of Applied Materials), so-called “low-k dielectrics”, and “ultra low-k dielectrics”, are principally used for electrically insulating layers.

Most often, the circuit comprises a silicon base with a polysilicon gate later attached thereto. A silicon nitride layer serves as electrical insulator. The silicon nitride layer and the polysilicon gate layer are in turn covered by an oxide layer, and a photoresist layer is deposited over the oxide layer. The photoresist layer is photographically defined into a mask. A subsequent etching step etches a contact hole through the oxide layer and stops on the silicon nitride layer.

While the thickness of the oxide layer cannot be reduced much below 500 to 1,000 nanometers (nm), the minimum feature sizes of contact via holes penetrating the oxide layer are continuously decreasing. The node, i.e. the distance between the walls of the etched items (e.g. contacts and holes), is permanently minimized. Light with a wavelength of 248 nm or 193 nm was applied for 130 nm nodes. For nodes with a wall distance of 90 nm and below, light with a wavelength of 193 nm is applied, and light with a wavelength of 157 nm to produce 65 nm nodes. The minimum feature size of contact and via holes is or will be shrinking to 45 nm, 32 nm and even only 22 nm. The immersion lithography technique allows to achieve definitions which can extend the use of this light source to the 32 nm node. “Extreme UV light” will supposedly be applied for the 22 nm node in the future. Some information about EUV light, e.g. EUV light with a wavelength of 13.5 nm, can be found in U.S. Pat. No. 7,372,059. Another technique which can be used to extend the application of the 193 nm light is the so called the “double patterning method”. It allows for the application of light of rather long wavelength, e.g. 193 nm, to produce very narrow nodes, e.g. even those with 90 nm nodes and gaps lower than 90 nm. A first photoresist is formed and developed, and then, a second photoresist is developed. This method is for example described in WO 008/036496.

Photoresists used in processes applying such light sources turned out to be rather “soft”, having not enough physical resistance under the conditions used in etching. Consequently, the edges of the photoresist were attacked by the etchant, with the result that the desired gap could not be achieved but formed a tapered gap. Several proposals to overcome this disadvantage are described by E. S. Moyer, J. Bremmer, C. Brick, P. F. Fu, A. Shirahata, S. Wang and C. Yeakle in Semiconductor International, published Saturday, Sep. 1, 2007. A technically feasible example is the “hard mask” method which provides a hard mask e.g. from carbon between the photoresist layer and the item to be etched. The hard mask allows for etching without a broadening of the etched hole or contact.

The disadvantage of these both processes is that an additional step is needed: either the application of a second photoresist pattern, or the application of the hard mask.

The current invention provides another approach to solve the problem associated with the softness of the photoresist by applying a fluorinated unsaturated C4 compound selected from the group consisting of trifluorobutadienes and tetrafluorobutenes as etchant. These compounds are considered as “soft” etchants especially suitable for the “soft” photoresists. Often, the compounds are applied together with argon, xenon, nitrogen and/or helium, optionally in the presence of hydrogen. If desired, they can be applied together with fluorinated compounds applicable as etchant, e.g. saturated perfluoroalkanes or saturated hydrofluoroalkanes, unsaturated perfluoroalkenes or perfluoroalkadienes or other unsaturated hydrofluoroalkenes or hydrofluoroalkadienes. For example, a polymerizing gas may be added, e.g. difluoromethane; but the compounds of the present invention have good polymerizing properties by themselves.

The etch process can be performed in a high-density plasma, such as an inductively coupled reactor, or a low-density plasma, such as a capacitively coupled reactor which is preferred. Often, the pressure is kept below about 20 millitorr.

Preferably, the fluorinated unsaturated C4 compound (or a mixture containing it) is introduced into the plasma reactor diluted with argon. If desired, etching could be divided into two sub steps wherein the fluorinated unsaturated C4 compounds are present, the first step being tuned for vertical profile; the second step is tuned for nitride selectivity and no etch stop. Often, a one step approach of etching and sidewall protection is preferred.

Mixtures of xenon (Xe) and argon (Ar) may be applied to tune the relative selectivity of the etchant chemistry between the dielectrics and the barrier layer, enhancing the selectivity.

The advantage of the C4 compounds of the present invention is the high selectivity, easy activation, and the formation of “gentle” plasma due to the H content and the multiple bond(s) in the molecules: H radicals formed in the plasma function as F radical scavengers. Thus, it is possible to avoid the additional step of applying a hard mask or double patterning. If desired, the C4 compounds nevertheless can be applied in such hard mask or double patterning processes.

Another aspect of the present invention concerns a composition of matter in the form of mixtures comprising or, preferably, consisting of at least one fluorinated unsaturated C4 compound selected from the group consisting of tetrafluorobutenes and trifluorobutadienes, and of a gas selected from the group consisting of nitrogen, helium, xenon, argon, and any combinations of two or more thereof. Optionally, additive gases, for example one or more hydrogen sources, e.g. hydrocarbons, preferably elemental hydrogen (which serves as fluorine trap in etching), or other passivating gases may be present. A “passivating gas” is a gas which forms a protective polymer layer; an example is CH₂F₂. In the following, these compositions of matter are often denoted as “mixtures”.

Mixtures containing or, preferably, consisting of xenon, argon, and at least one fluorinated unsaturated C4 compound selected from the group of tetrafluorobutenes and trifluorobutadienes, are especially preferred.

One embodiment concerns mixtures containing or, preferably, consisting of at least one tetrafluorobutene and a gas selected from the group consisting of nitrogen, helium, xenon, argon, and any combinations of two or more thereof, and optionally at least one hydrogen source, preferably hydrogen.

The trifluorobutadiene is preferably 1,1,3-trifluoro-1,3-butadiene.

The tetrafluorobutene is preferably (E)-1,1,1,3-tetrafluoro-2-butene, (Z)-1,1,1,3-tetrafluoro-2-butene, or 2,4,4,4-tetrafluoro-1-butene.

Preferably, the composition of matter contains or, preferably, consists of a fluorinated unsaturated C4 compound selected from the group consisting of (E)-1,1,1,3-tetrafluoro-2-butene, (Z)-1,1,1,3-tetrafluoro-2-butene, 2,4,4,4-tetrafluoro-1-butene, and any combinations of two or more thereof, and a gas selected from the group consisting of xenon, argon, nitrogen, and any combinations of two or more of said gases. In this preferred embodiment, xenon, argon and mixtures thereof are preferred gases.

The following non-limiting mixtures are preferred:

A mixture containing or, preferably, consisting of 2,4,4,4-tetrafluoro-1-butene and at least one additional compound selected from the group consisting of nitrogen, helium, xenon, and argon, optionally also comprising hydrogen. Mixtures containing or, preferably, consisting of 2,4,4,4-tetrafluoro-1-butene and at least one additional compound selected from the group consisting of xenon and argon are especially preferred. Mixtures containing or, preferably, consisting of 2,4,4,4-tetrafluoro-1-butene, xenon and argon are most preferred.

A mixture containing or, preferably, consisting of (E)-1,1,1,3-tetrafluoro-2-butene and at least one additional compound selected from the group consisting of nitrogen, helium, xenon, and argon, optionally also comprising hydrogen. Mixtures containing or, preferably, consisting of (E)-1,1,1,3-tetrafluoro-2-butene and at least one additional compound selected from the group consisting of xenon and argon are especially preferred. Mixtures containing or, preferably, consisting of (E)-1,1,1,3-tetrafluoro-2-butene, xenon and argon are most preferred.

A mixture containing or, preferably, consisting of (Z)-1,1,1,3-tetrafluoro-2-butene and at least one additional compound selected from the group consisting of nitrogen, helium, xenon, and argon, optionally also comprising hydrogen. Mixtures containing or, preferably, consisting of (Z)-1,1,1,3-tetrafluoro-2-butene and at least one additional compound selected from the group consisting of xenon and argon are especially preferred. Mixtures containing or, preferably, consisting of (Z)-1,1,1,3-tetrafluoro-2-butene, xenon and argon are most preferred.

Thus, among the three especially preferred kinds of mixtures mentioned hereabove, those mixtures are most preferred which contain or consist of the respective tetrafluorobutene, xenon and argon.

Another embodiment concerns mixtures containing or, preferably, consisting of trifluorobutadienes and at least one additional compound selected from the group consisting of nitrogen, helium, xenon and argon, and optionally additionally hydrogen.

Preferred mixtures comprise or, preferably, consist of 1,1,2-trifluoro-1,3-butadiene and at least one additional compound selected from the group consisting of nitrogen, helium, xenon and argon, and optionally additionally hydrogen. Mixtures comprising or consisting of 1,1,2-trifluoro-1,3-butadiene and xenon, argon or argon and xenon are especially preferred. Also here, mixtures comprising 1,1,2-trifluoro-1,3-butadiene and xenon and argon are especially preferred.

These mixtures are very suitable as etching gases with passivating capability.

In preferred mixtures, the content of the fluorinated unsaturated C4 compound is equal to or greater than 10% by volume. Preferably, it is equal to or lower than 50% by volume. Preferably, nitrogen, helium, xenon, and/or argon are the balance to 100% by volume. The mixtures can be free of hydrogen. If hydrogen is present, it is preferably comprised from 2 to 10% by volume. The percentages given here refer to the gaseous state.

Preferably, the volume ratio between argon and the at least one fluorinated unsaturated C4 compound selected from the group consisting of 1,1,3-trifluoro-1,3-butadiene, (E)-1,1,1,3-tetrafluoro-2-butene, (Z)-1,1,1,3-tetrafluoro-2-butene, 2,4,4,4-tetrafluoro-1-butene, and any combinations of two or more thereof, is equal to or greater than 1:1, preferably equal to or greater than 2:1, more preferably equal to or greater than 3:1 and especially preferably equal to or greater than 4:1.

According to one embodiment, these mixtures are in gaseous form and thus are gas mixtures.

The gas mixture according to the present invention comprises or, preferably, consists of at least one fluorinated unsaturated C4 compound selected from the group consisting of trifluorobutadienes and tetrafluorobutenes, and a gas selected from the group consisting of nitrogen, xenon, helium, argon, and any combinations of two or more thereof.

Preferably, the trifluorobutadiene is 1,1,3-trifluoro-1,3-butadiene.

Preferably, the tetrafluorobutene is (E)-1,1,1,3-tetrafluoro-2-butene, (Z)-1,1,1,3-tetrafluoro-2-butene, or 2,4,4,4-tetrafluoro-1-butene.

A preferred gas mixture comprises or, preferably, consists of one fluorinated unsaturated C4 compound selected from the group consisting of (E)-1,1,1,3-tetrafluoro-2-butene, (Z)-1,1,1,3-tetrafluoro-2-butene, 2,4,4,4-tetrafluoro-1-butene, and any combinations of two or more thereof, and a gas selected from the group consisting of xenon, argon, nitrogen, and any combinations of two or more thereof.

A still more preferred gas mixture comprises or consists of one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof; and a gas selected from the group consisting of xenon, argon, and any combinations thereof.

Preferably, the volume ratio between argon and the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof is equal to or greater than 1:1, preferably equal to or greater than 2:1, more preferably equal to or greater than 3:1 and especially preferably equal to or greater than 4:1.

Gas mixtures comprising xenon are especially preferred.

According to another embodiment, the mixtures are at least partially in condensed form, e.g. being pressurized or kept at low temperature. In this embodiment, the mixtures are liquid or a composition matter in a partially liquid and partially gaseous state. If these mixtures are compressed in a storage tank (e.g. in a pressure cylinder, a tank or the like), a gas phase may form above the condensed liquid. The contents of fluorinated unsaturated C4 hydrocarbon selected from the group consisting of trifluorobutadienes and tetrafluorobutenes, and the gas selected from the group consisting of nitrogen, xenon, helium, argon, and any combinations of two or more thereof, and preferred embodiments thereof, correspond to the compositions or mixtures and gas mixtures mentioned above.

For some applications, in the gas mixture or the condensed composition, the volume ratio between the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof, and argon may be equal to or greater than 1:1, preferably equal to or greater than 2:1, more preferably equal to or greater than 3:1 and especially preferably equal to or greater than 4:1.

The unsaturated C4 compounds are very suitable as etching agent in the manufacture of memory or a logic circuit, for example, a DRAM or CPU. They are especially suitable for anisotropic etching of nodes with very narrow gaps, e.g. the 90 nm node, the 45 nm and 32 nm nodes and even the 22 nm node. They are used in gaseous or vapor form. The C4 compounds of the present invention have good polymer-forming properties and can be easily produced from commercially available compounds.

If they are applied together with gases such as nitrogen, helium, xenon, argon, and any combinations of two or more thereof, or one or more hydrogen sources, e.g. hydrocarbons or, preferably, elemental hydrogen, then one can introduce the components separately into the reactor. Alternatively, they can be premixed, e.g. by introducing the components into a common line connected to the reactor. In another alternative, the components are stored as a mixture in a storage tank, i.e. they are present in mixed form therein and can be drawn off and introduced into the reactor in perfectly mixed form.

The following examples are intended to explain the invention in further detail without the intention to limit it.

### EXAMPLE 1

### Compositions of Matter Especially Suitable for Anisotropic Etching

Etching compositions are prepared by condensing the respective unsaturated C4 compound, argon and optionally nitrogen and hydrogen, respectively, in a pressure-resistant storage tank.

2,4,4,4-tetrafluoro-1-butene, (E)-1,1,1,3-tetrafluoro-2-butene, (Z)-1,1,1,3-tetrafluoro-2-butene and 1,1,3-trifluorobutadiene can be prepared thermally or catalytically from 1,1,1,3,3-pentafluorobutane by dehydrofluorination, as described in WO 2004/096737 or as described in WO 2009/010472 from 1,1,1,3,3-pentafluorobutane over a high-surface aluminium fluoride catalyst. The content of 1,1,3-trifluorobutadiene in the product mixture containing 2,4,4,4-tetrafluoro-1-butene, (E)-1,1,1,3-tetrafluoro-2-butene, (Z)-1,1,1,3-tetrafluoro-2-butene and 1,1,3-trifluorobutadiene depends on the reaction temperature. The higher the reaction temperature, the higher the content of 1,1,3-trifluorobutadiene. Separation of these compounds is possible by distillation. (E)-1,1,1,3-tetrafluoro-2-butene, for example, has a boiling point of about 18 to 19° C. (Z)-1,1,1,3-tetrafluoro-2-butene has a boiling point of about 49° C.

TABLE 1
Etching compositions (amounts given in % by volume)

| Example | C₄F₃H₃* | Ar | Xe or N₂ | H₂ |
|---|---|---|---|---|
| 1.1 | 15 | 85 | — | — |
| 1.2 | 20 | 80 | — | — |
| 1.3 | 30 | 70 | — | — |
| 1.4 | 15 | 75 | — | 10 |
| 1.5 | 20 | 70 | — | 10 |
| 1.6 | 20 | 75 | Xe: 5 | — |
| 1.7 | 20 | 75 | Xe: 0 N₂: 5 | |

*1,1,3-trifluoro-1,3-butadiene

| Example | C₄F₄H₂* | Ar | Xe or N₂ | H₂ |
|---|---|---|---|---|
| 2.1 | 10 | 90 | — | — |
| 2.2 | 15 | 85 | — | — |
| 2.3 | 20 | 80 | — | — |
| 2.4 | 20 | 75 | — | 5 |
| 2.5 | 20 | 70 | Xe: 10 | — |
| 2.6 | 20 | 70 | Xe: 0 N₂: 10 | |

*1,1,1,3-tetrafluoro-2-butene, (E) isomer

| | | | | |
|---|---|---|---|---|
| 3.1 | 10 | 90 | — | — |
| 3.2 | 15 | 85 | — | — |
| 3.3 | 20 | 80 | — | — |
| 3.4 | 20 | 75 | — | 5 |
| 3.5 | 20 | 70 | Xe: 10 | — |
| 3.6 | 20 | 70 | Xe: 0 N₂: 10 | |

*1,1,1,3-tetrafluoro-2-butene, (Z) isomer

| | | | | |
|---|---|---|---|---|
| 4.1 | 10 | 90 | — | — |
| 4.2 | 15 | 85 | — | — |
| 4.3 | 20 | 80 | — | — |
| 4.4 | 20 | 75 | — | 5 |
| 4.5 | 20 | 70 | Xe: 10 | — |
| 4.6 | 20 | 70 | Xe: 0 N₂: 10 | |

*2,2,2,4-tetrafluoro-1-butene

The compositions mentioned above are prepared by pressing and/or condensing the respective gases and liquids in a pressure resistant storage tank. When taken out of the storage tank under a pressure lower than ambient pressure (about 1 bar abs.), they form corresponding gas mixtures which are suitable as etching gases.

### EXAMPLE 2

### Manufacture of a Semiconductor

Etching can be performed in an Inductive Coupled Plasma Source (ICP) etch reactor or in a Capacitively Coupled Plasma Source (CCP) reactor which is available from Applied Materials. A self-aligned contact (SAC) is formed as described in FIG. 1 and page 3 of WO 2000/302168. A polysilicon gate layer, a tungsten silicide barrier and glue layer, and a silicon nitride cap layer are deposited and photolithographically formed into two closely related spaced gate structures having a gap there between. Then, a silicon nitride layer is deposited via CVD on the structure, and dopant ions are implanted. A dielectric SiO₂ layer is deposited over the structure, a photoresist layer is deposited over the over the oxide layer and photographically defined using light with a wavelength of 193 nm into a mask. Then, using 1,1,3-trifluorobutadiene and argon, delivered in a weight ratio of 1:4 into the plasma reactor, the SiO₂ layer is etched. A contact hole with a diameter of less than 50 nm is achieved with an aspect ratio of >20.

In this process, 1,1,3-trifluorobutadiene and argon can be fed into the plasma reactor separately from each other, or premixed in the form of a gas mixture. If desired, the gas mixture can be taken from a storage tank comprising a liquefied composition of matter consisting of 1,1,3-trifluorobutadiene and argon.

### EXAMPLE 3

### Example 2 is Repeated Using Low-K Dielectric Layers or Ultra-Low-K Dielectric Layers Instead of SiO₂ Layers

### EXAMPLE 4

### Manufacture of a semiconductor using 2,2,2,4-tetrafluoro-1-butene

Example 2 is repeated using a gaseous mixture containing 20% by volume of 2,2,2,4-tetrafluoro1-butene, 70 vol-% of argon, and 10 vol-% xenon. The gas mixture is taken from a storage tank containing this gas mixture in liquid form.

### EXAMPLE 5

### Manufacture of a semiconductor using (E)-1,1,1,3-tetrafluoro-2-butene

Example 2 is repeated using a gaseous mixture containing 20% by volume of (E)-1,1,1,3-tetrafluoro2-butene, 70 vol-% of argon, and 10 vol-% xenon. The gas mixture is taken from a storage tank containing this gas mixture in liquid form.

### EXAMPLE 6

### Manufacture of a semiconductor using (Z)-1,1,1,3-tetrafluoro-2-butene

Example 2 is repeated using a gaseous mixture containing 20% by volume of (Z)-1,1,1,3-tetrafluoro2-butene, 70 vol-% of argon, and 10 vol-% xenon. The gas mixture is taken from a storage tank containing this gas mixture in liquid form.

### EXAMPLE 7

### Manufacture of a semiconductor using (E)-1,1,1,3-tetrafluoro-2-butene

Example 6 is repeated by introducing (E)-1,1,1,3-tetrafluoro2-butene, argon and xenon separately from each other into the plasma reactor such that a gaseous mixture containing 20% by volume of (E)-1,1,1,3-tetrafluoro2-butene, 70 vol-% of argon, and 10 vol-% xenon is formed in the reactor.

### EXAMPLE 8

### Manufacture of a semiconductor using (E)-1,1,1,3-tetrafluoro-2-butene

Example 6 is repeated by introducing (E)-1,1,1,3-tetrafluoro2-butene, argon and xenon separately from each other into a common line such that a gaseous mixture containing 20% by volume of (E)-1,1,1,3-tetrafluoro2-butene, 70 vol-% of argon, and 10 vol-% xenon is formed in the line. In this line, they are premixed and introduced together as premixed gas mixture into the plasma reactor.

1. A process for producing an etched item including least one step of anisotropic etching the item wherein the etching of the item is performed in the presence of at least one fluorinated unsaturated C4 compound selected from the group consisting of trifluorobutadienes and tetrafluorobutenes.

2. The process of claim 1 wherein the item is a semiconductor memory or a semiconductor logic circuit.

3. The process of claim 1 wherein a photoresist is applied for photolithographical definition of a pattern wherein the photoresist is selected among photoresists definable by light with a wavelength of less than 248 nm, 193 nm, or in the “extreme UV light” region.

4. The process of claim 3 for etching a gap of a contact or hole wherein the gap of the contact or hole is 130 nm, 90 nm, 45 nm, 32 nm, or 22 nm.

5. The process of claim 1 wherein the fluorinated unsaturated C4 compound is applied together with a gas selected from the group consisting of nitrogen, xenon, helium, argon, and any combinations of two or more thereof.

6. The process according to claim 5 wherein the fluorinated unsaturated C4 compound is applied together with xenon and argon.

7. The process according to claim 1 wherein the anisotropic etching is performed in the presence of 1,1,3-trifluorobutadiene; a tetrafluorobutene with a trifluoro-substituted carbon atom; or any combinations thereof.

8. The process according to claim 7 wherein the process is performed in the presence of 1,1,3-trifluorobutadiene; (E)-1,1,1,3-tetrafluoro-2-butene; (Z)-1,1,1,3-tetrafluoro-2-butene; 2,4,4,4-tetrafluoro-1-butene; or any combinations of two or more thereof.

9. A composition of matter comprising or consisting of at least one fluorinated unsaturated C4 compound selected from the group consisting of trifluorobutadienes and tetrafluorobutenes, and a gas selected from the group consisting of nitrogen, xenon, helium, argon, and any combinations of two or more thereof.

10. The composition of matter of claim 9 wherein the trifluorobutadiene is 1,1,3-trifluoro-1,3-butadiene.

11. The composition of matter of claim 9 wherein the tetrafluorobutene is (E)-1,1,1,3-tetrafluoro-2-butene, (Z)-1,1,1,3-tetrafluoro-2-butene, or 2,4,4,4-tetrafluoro-1-butene.

12. The composition of matter of claim 9 consisting of one fluorinated unsaturated C4 compound selected from the group consisting of (E)-1,1,1,3-tetrafluoro-2-butene, (Z)-1,1,1,3-tetrafluoro-2-butene, 2,4,4,4-tetrafluoro-1-butene, and any combinations of two or more thereof, and a gas selected from the group consisting of xenon, argon, nitrogen, and any combinations of two or more thereof.

13. The composition of matter of claim 10 comprising or consisting of one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof; and a gas selected from the group consisting of xenon, argon, and any combinations thereof.

14. The composition of matter of claim 13 wherein the volume ratio between argon and the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof is equal to or greater than 1:1.

15. The composition of matter of claim 9 comprising xenon.

16. The composition of matter of claim 9 which is a gas mixture.

17. The composition of matter of claim 14 wherein the volume ratio between argon and the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof is equal to or greater than 2:1.

18. The composition of matter of claim 14 wherein the volume ratio between argon and the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof is equal to or greater than 3:1.

19. The composition of matter of claim 14 wherein the volume ratio between argon and the at least one fluorinated unsaturated C4 compound selected from the group consisting of 1,1,3-trifluoro-1,3-butadiene, (Z)-1,1,1,3-tetrafluoro-2-butene, (E)-1,1,1,3-tetrafluoro-2-butene, 2,4,4,4-tetrafluoro-1-butene, and any combinations of two or more thereof is equal to or greater than 4:1.
